(19) United States
(12) Patent Application Publication
(10) Pub. No.: US 2015/0340633 A1
(43) Pub. Date: Nov. 26, 2015

(54) ORGANIC SOLAR CELL OF THE BULK HETEROJUNCTION TYPE COMPRISING AN IMIDE BASED CONJUGATED BACKBONE COMPOUND AS PHOTOACTIVE MATERIAL

(71) Applicant: TATA STEEL NEDERLAND TECHNOLOGY B.V., Ijmuiden (NL)

(72) Inventors: Ganesan PALANISWAMY, BEVERWIJK (NL); Fouzia HANNOUR, HAARLEM (NL); Theodorus Jacobus DINGEMANS, LEIDEN (NL); Ricardo Klaas Maarten BOUWER, DELFT (NL)

(73) Assignee: TATA STEEL NEDERLAND TECHNOLOGY B.V., Ijmuiden (NL)

(21) Appl. No.: 14/409,811

(22) PCT Filed: May 31, 2013
(86) PCT No.: PCT/EP2013/001599

§ 371 Date: Dec. 19, 2014

(30) Foreign Application Priority Data
Jun. 25, 2012 (EP) 12004754.3

(51) Int. Cl. H01L 51/42; H01L 51/00

(52) U.S. Cl. CPC H01L 51/4253; H01L 51/0061; H01L 2051/0063; H01L 51/0072; H01L 51/007; H01L 51/0068; H01L 51/0069; H01L 51/0071; H01L 51/0074

(57) ABSTRACT

A solar cell including at least a substrate, a cathode, a hole conductive layer, a bulk heterojunction photoactive layer of a blend of a donor material and an acceptor material, an electron conductive layer and an anode, wherein the blend includes at least one photoactive material including a conjugated backbone system having:
i) the general formula R2-imide-Ar-L-Ar-imide-R3, wherein
   Ar-L-Ar is a conjugated chromophore
   imide is imide —OCNCO—
   R2 and R3 are organic groups, bonded to the N atom of the respective imide and forming a conjugated bond with the respective imide; or.
ii) repeating units (R4-imide-Ar-L-Ar-imide)n, wherein
   Ar-L-Ar is a conjugated chromophore
   imide is imide —OCNCO—
   R4 is an organic group bonded to the N atom of the respective imide and forming a conjugated bond with the respective imide
   and n is the number of repeating units.

The present invention relates to an organic solar cell of the bulk heterojunction (BHJ) type. Generally such a solar cell comprises at least a substrate, a cathode, a hole conductive layer, a bulk heterojunction photoactive layer of a blend of a donor material and an acceptor material, an electron conductive layer and an anode.

Photovoltaic devices constructed of organic photoactive materials—hereinafter organic solar cells—have gained much scientific attention due to the promise of easy processing, light weight and potentially low cost. Many of these organic solar cells comprise photoactive material based on conjugated polymers as electron donor and hole conductor. Because polymer processing is well-developed, it is expected that known roll-to-roll processing techniques like doctor-blading, spraying, printing and roll-coating can be applied in manufacturing organic solar cells, in particular large-area, inexpensive solar cells on flexible supports, which would open a tremendous number of possible applications. Interest in organic solar cells has further increased due to the discovery of the so called bulk heterojunction concept, which focuses on inter alia at optimizing the interface between the donor and acceptor organic phases in a blend thereof, where excitons dissociate into electrons and holes and thus cause charge flow.

Traditionally, conjugated compounds such as MDMO-PPV, P3HT and the likes are used as donor phase in order to absorb light and generate and transfer excitons to the interface with the acceptor phase, where exciton dissociation occurs. For the acceptor phase C60, PCBM, CN—PPV and the likes are frequently used as exemplary materials.

One of the drawbacks of these known photoactive materials, whether donor or acceptor, is related to their complex procedure of synthesizing including purification in order to remove metal catalysts used in the synthesis, to obtain electronic grade materials. Stringent conditions are required both during preparation of these materials, as well as during production of the solar cells derived thereof. Moreover, these materials are sensitive to oxygen and water vapour. This sensitivity involves the risk of degradation and changes of morphology, especially at temperatures above room temperature, and thus a reduced efficiency and a limited lifetime of the photoactive material are likely to occur.

It is an object of the present invention to provide an organic solar cell of the bulk heterojunction type wherein the photoactive material, whether donor or acceptor depending on the respective electron affinity, does not have the above mentioned disadvantages of the known materials, or at least to a lesser extent.

Furthermore it is an object of the present invention to provide such a solar cell comprising a photoactive material, which can be prepared using a simple process.

Another object of the present invention is to provide an organic solar cell of the bulk heterojunction type having a long service life, more particularly such a cell comprising a photoactive material that shows an improved stability and/or fixed morphology during its entire service period.

According to the invention one or more of the above objects are achieved by a solar cell, comprising at least a substrate, a cathode, a hole conductive layer, a bulk heterojunction photoactive layer of a blend of a donor material and an acceptor material, an electron conductive layer and an anode, wherein the blend comprises at least one photoactive material comprising a conjugated backbone system having:

i) the general formula R2-imide-Ar-L-Ar-imide-R3, wherein
Ar-L-Ar is a conjugated chromophore,
imide is imide —OCNCO—,
R2 and R3 are organic groups, bonded to the N atom of the respective imide and forming a conjugated bond with the respective imide; or.

ii) having repeating units (R4-imide-Ar-L-Ar-imide)n, wherein
Ar-L-Ar is a conjugated chromophore
imide is imide —OCNCO—
R4 is an organic group bonded to the N atom of the respective imide and forming a conjugated bond with the respective imide
and n is the number of repeating units.

In the solar cell according to the invention having a common configuration the blend contained in the bulk heterojuction photoactive layer comprises an imide based conjugated backbone compound as at least one of the donor or acceptor. This compound is either a small (“single”) molecule having the general formula R2-imide-Ar-L-Ar-imide-R3 as defined in i) or a polymeric compound having repeating units (R4-imide-Ar-L-Ar-imide)n. In the compounds the conjugated chromophore(s), Ar-L-Ar, and the conjugated imide groups as well as the organic groups R2, R3 and R4 respectively that form a conjugated bond with the N atom of the respective imide groups, are part of the conjugated bond system of the main chain of the compound. Thus R2, R3 and R4 comprise at least a double bond between the first carbon atom attached to the N atom of the imide group and the adjacent carbon atom. Preferably the conjugated bond system extends throughout the R2, R3 and/or R4 hydrocarbon groups. Depending on its counterpart and on the electron affinities the photoactive material acts as a donor or as an acceptor in the solar cell according to the invention. This photoactive material having a di- or polyimide based conjugated backbone that also comprises a conjugated chromophore within its conjugated backbone is temperature and chemical resistant, and shows an improved tolerance towards oxygen and moisture compared to state of the art materials. Generally, the photoactive material used in the solar cell according to the invention possesses a fixed morphology, even at temperatures above ambient and an improved service life, because the photoactive material upon imidization and polymerization, if any, will not undergo additional chemical reactions or reorientation.

Here it is noted that imide based compounds as such are known. E.g JP04306234 has disclosed a polyimide copolymer having a structural unit IV, wherein R is a bifunctional organic group (preferably derived from a long-chain aromatic diamine used in its preparation) and m is 1 to 3

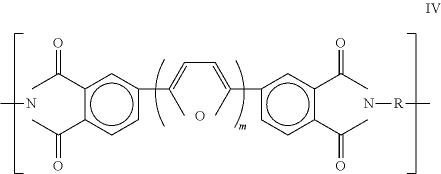

Such a copolymer comprises a conjugated backbone comprising a furan moiety, at least two imide groups —OCNCO—, and R being an organic group. It is said that this polyimide copolymer has excellent heat resistance, high modulus of elasticity, low thermal expansion, low dielectric constant and low water vapour absorption.

From WO 2011/158211 A1 an organic semiconductor material, in particular having n type characteristics for a thin film transistor, having formula (F) is known,

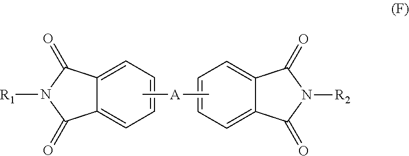

wherein A represents a cyclic conjugated skeleton structure comprising at least one aromatic ring and R1 and R2 are each independently a substituted or unsubstituted alkyl group. Due to this nature of R1 and R2 these groups do not form a conjugated bond system throughout the main chain. It is said that fluorine-substituted alkyl groups as R1 and R2 in formula (F) allow to prevent impurities such as water, oxygen and air from penetrating into an organic semiconductor thin film, and therefore, to exhibit stable n-type semiconductor characteristics.

JP 2010254608 A discloses a photoelectric converter material for use in an organic thin film solar cell. This known material comprises a compound

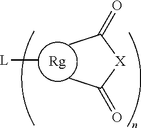

wherein L is a divalent or trivalent group, Rg is a substituted or unsubstituted benzene or naphthalene ring, X is O or NR1, wherein R1 can be among others a substituted or unsubstituted C1-20 alkenyl group. This material is used as a charge transport compound for replacing LiF in a typical bilayer solar cell design.

The concept of the present invention allows to select an appropriate chromophore Ar-L-Ar, in particular the L moiety thereof which gives the flexibility to adjust to the desired properties, such as light absorption in the near UV and visible spectrum, in particular the latter. In this way, a molecule can be designed to be a donor as well as an acceptor, as the chromophore is the part of the compound predominantly responsible for absorption.

The groups R2, R3, R4 attached to the nitrogen atom of the imide group extend the conjugated system and contribute to the absorption of light, as well are considered a solubilising group for solubilising the photoactive material in the solvents typically used in the production of organic solar cells. Preferably the groups R1, R2 and R2 are selected from a substituted or unsubstituted alkenyl group, a substituted or unsubstituted unsaturated cyclic hydrocarbon group.

In the invention the L moiety of the at least one conjugated chromophore is not attached directly to an imide group in the conjugated backbone, but an intermediate coupling group Ar is positioned between the respective imide groups and the L moiety. Ar is a conjugated organic group. Fluorene and carbazole are examples thereof. More preferably Ar is an aryl group, such as a phenyl group. The conjugated organic group may be substituted. Advantageously the L moiety comprises a conjugated organic group, advantageously a mono- or polycyclic group, comprising at least a heteroatom selected from Si, S, N and O. Preferably the L moiety comprises at least one 5 membered organic ring group comprising 1-3 heteroatoms selected from Si, S, N and O. In a polycyclic L moiety, for example said 5 membered organic ring group may be fused to a further 5 or 6 membered organic group having conjugated bonds.

In a preferred embodiment of the solar cell according to the invention the photoactive material as defined functions as a donor. Known acceptor materials may be used as counterparts. Preferably the blend comprises different photoactive materials according to the invention, both as a donor and an acceptor.

The photoactive material comprises at least two imide groups in the conjugated backbone. The part consisting of imide—Ar preferably comprises a phtalimide group for synthetic reasons. The photoactive material having an imide based conjugated backbone can be a small molecule comprising at least two imide moieties in the conjugated system thereof.

In the embodiment of small molecules the photoactive material comprises compounds having the general formula R2-imide-Ar-L-Ar-imide-R3,

wherein
Ar-L-Ar is a conjugated chromophore as explained above including the above preferences for the L moiety and conjugated organic group Ar; imide is imide —OCNCO—; and
R2 and R3 are organic groups bonded to the N atom of the imide and forming a conjugated bond with the respective imide group. Typically R2 and R3 are identical.

Typical examples of photoactive material used in the solar cell according to the invention include

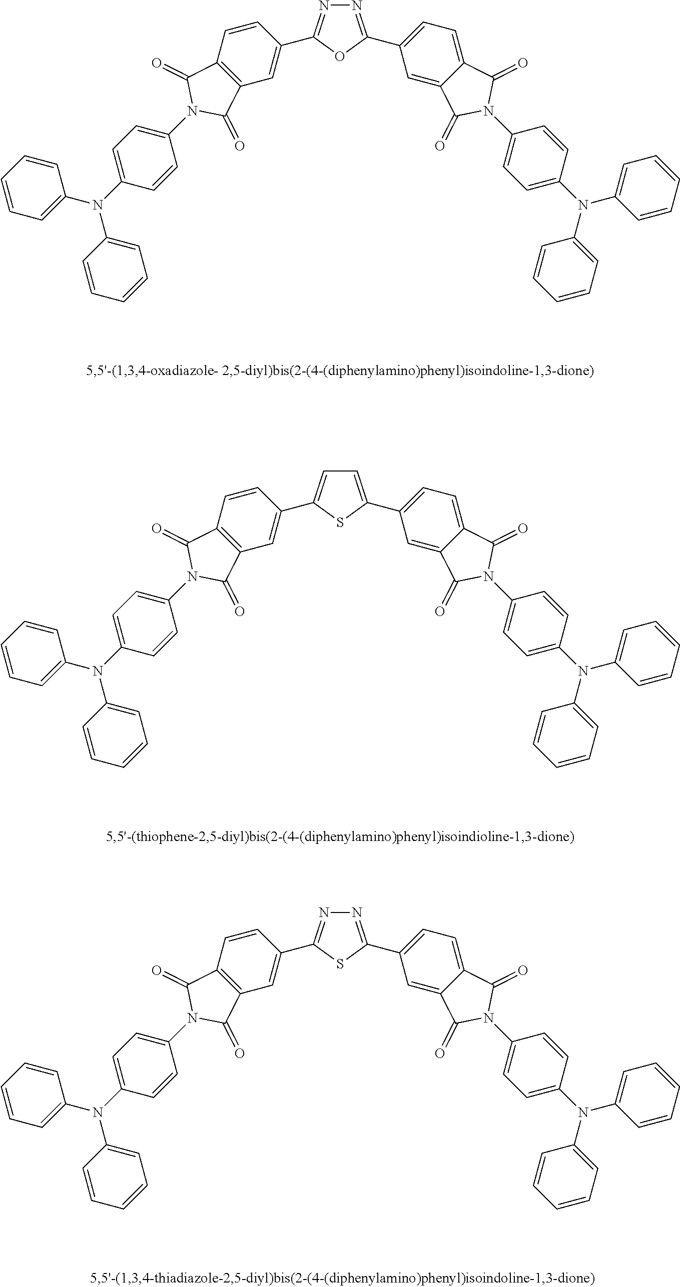 [SMILES: O=C1c2ccc(-c3nnc(-c4ccc5c(c4)C(=O)N(c4ccc(N(c6ccccc6)c6ccccc6)cc4)C5=O)o3)cc2C(=O)N1c1ccc(N(c2ccccc2)c2ccccc2)cc1 ; O=C1c2ccc(-c3ccc(-c4ccc5c(c4)C(=O)N(c4ccc(N(c6ccccc6)c6ccccc6)cc4)C5=O)s3)cc2C(=O)N1c1ccc(N(c2ccccc2)c2ccccc2)cc1 ; O=C1c2ccc(-c3nnc(-c4ccc5c(c4)C(=O)N(c4ccc(N(c6ccccc6)c6ccccc6)cc4)C5=O)s3)cc2C(=O)N1c1ccc(N(c2ccccc2)c2ccccc2)cc1]

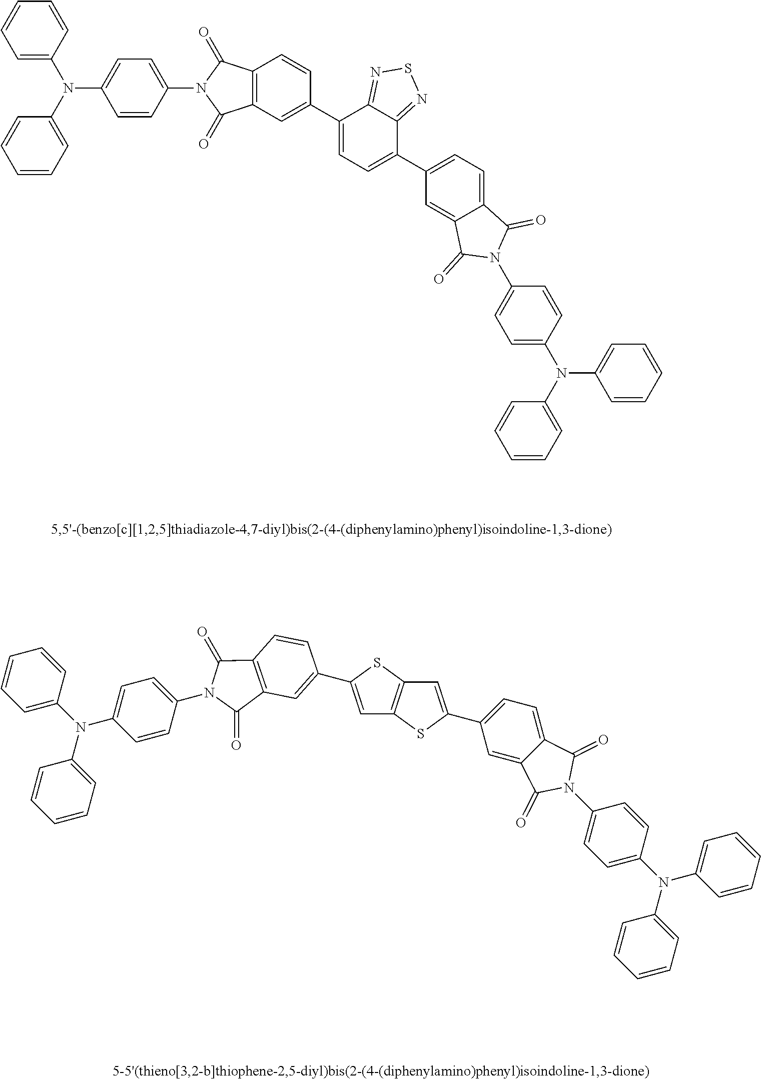 [SMILES: O=C1c2ccc(-c3ccc(-c4ccc5c(c4)C(=O)N(c4ccc(N(c6ccccc6)c6ccccc6)cc4)C5=O)c4nsnc34)cc2C(=O)N1c1ccc(N(c2ccccc2)c2ccccc2)cc1 ; O=C1c2ccc(-c3cc4sc(-c5ccc6c(c5)C(=O)N(c5ccc(N(c7ccccc7)c7ccccc7)cc5)C6=O)cc4s3)cc2C(=O)N1c1ccc(N(c2ccccc2)c2ccccc2)cc1]

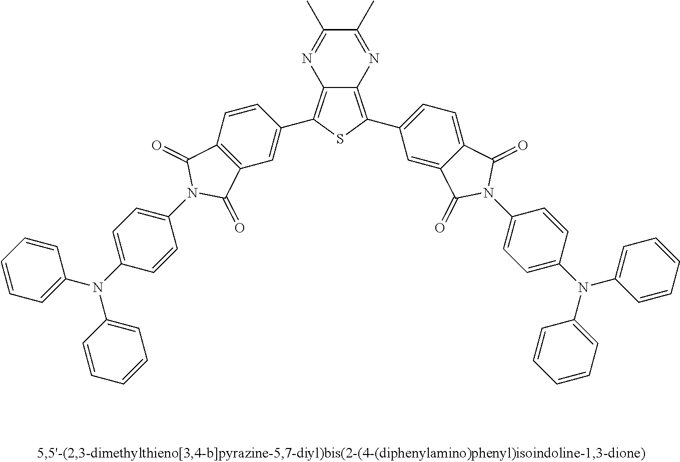 [SMILES: Cc1nc2c(-c3ccc4c(c3)C(=O)N(c3ccc(N(c5ccccc5)c5ccccc5)cc3)C4=O)sc(-c3ccc4c(c3)C(=O)N(c3ccc(N(c5ccccc5)c5ccccc5)cc3)C4=O)c2nc1C]

In the polymeric embodiment of the photoactive material as used in the solar cell according to the invention, the photoactive material comprises polymers having repeating units (R4-imide-Ar-L-Ar-imide)n, wherein
Ar-L-Ar is a conjugated chromophore
imide is imide —OCNCO—;
R4 is an organic group bonded to the N atom of the imide forming a conjugated bond with the respective imide; and
n is the number of repeating units.

Advantageous and preferred embodiments of the L moiety and group Ar in the conjugated chromophore Ar-L-Ar are as defined above. The number of repeating units is not specifically limited, commonly it will be in the range of about 200 to about e.g. 6000.

Examples of the L moiety comprising at least one heteroatom include the compounds comprising one or two 5 or 6 membered rings comprising a heteroatom shown below in the left column. The second column shows examples of group R4 in polymeric compounds used in the invention. The third to fifth column show typical examples of groups R2 and R3 in small molecules in the invention.

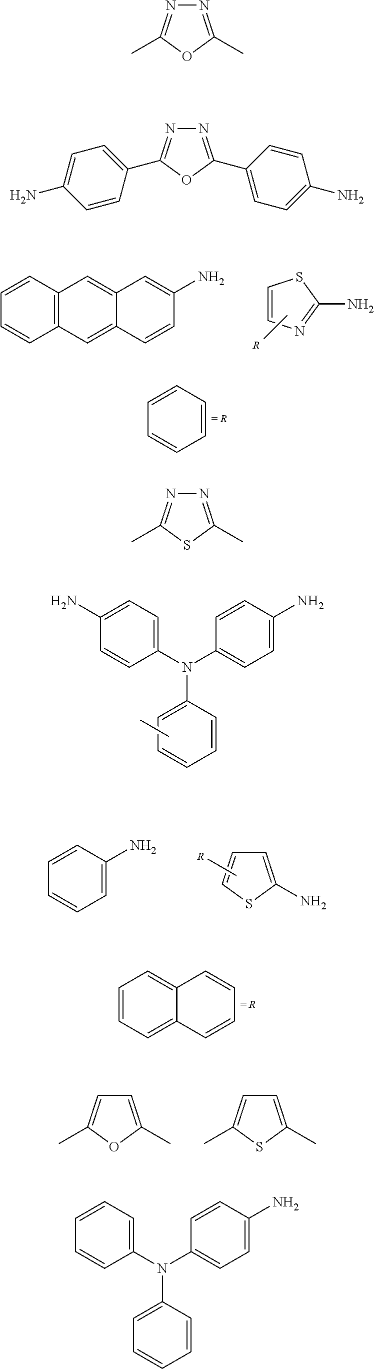

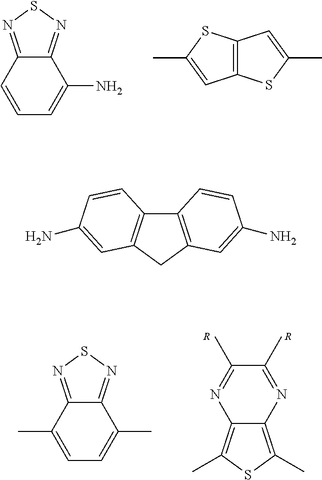

Regarding organic groups R2, R3 and R4 they can be any group that forms a conjugated bond with the respective imide group. Examples include inter alia the aromatic amines illustrated above, as well as the aromatics at the right hand.

The photoactive material used in the solar cell according to the invention can be easily prepared, e.g. using a method comprising an imidization reaction of an (aromatic) carboxylic acid dianhydride with an amine R2-NH2, preferably an aromatic amine, thereby obtaining a conjugated bond at the imide moieties thus formed, wherein R2 is defined as above and takes part in the conjugated bond system.

In manufacturing a polymeric photoactive material as used in the invention the dianhydride is allowed to react with a diamine.

The invention is further illustrated by the attached drawing and examples In the drawing

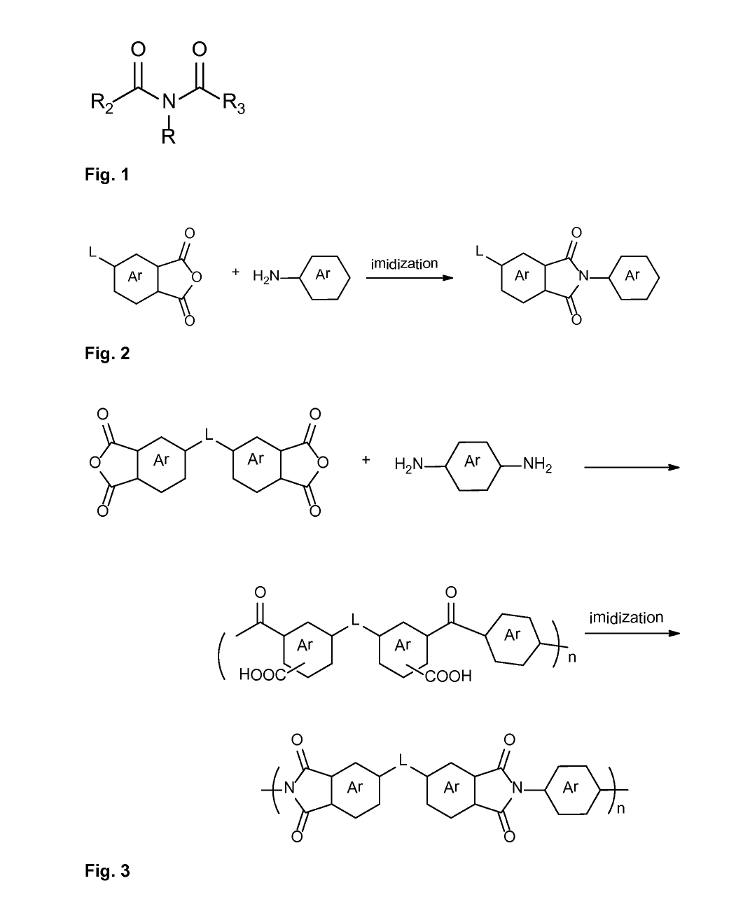

FIG. 1 shows an imide moiety.

FIGS. 2 and 3 show synthetic routes, of which FIG. 3 is illustrative for preparing an imide backbone structure of the photoactive layer used in a solar cell according to the invention;

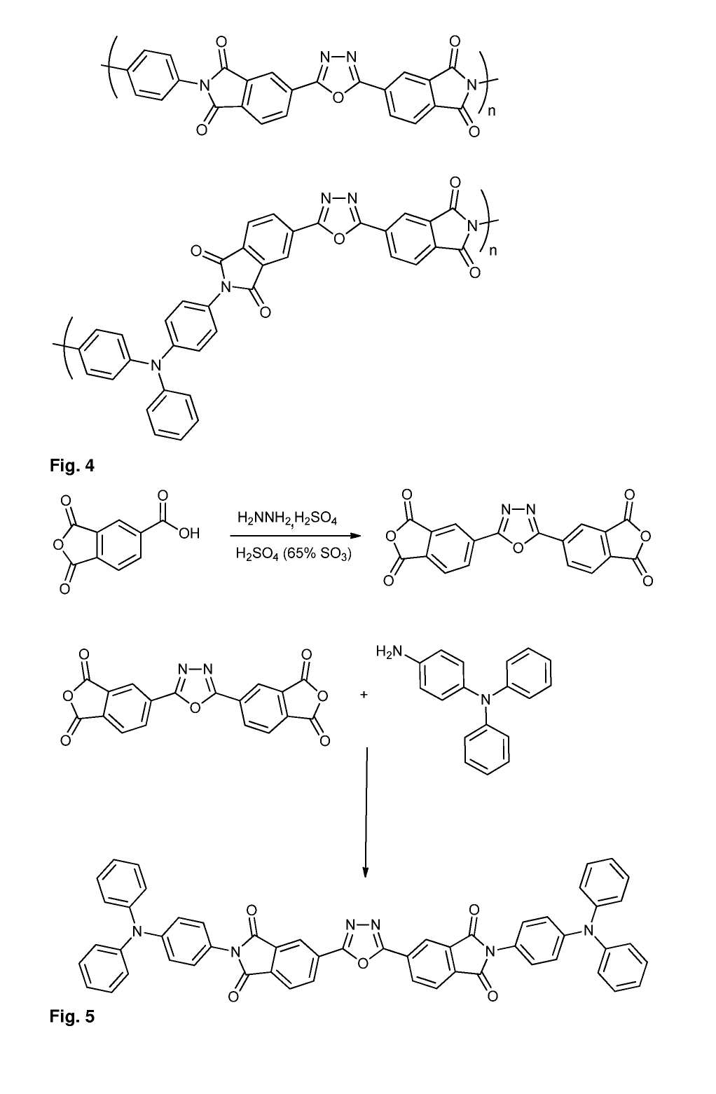

FIG. 4 shows examples of small molecular (oligomeric) and polymeric imides;

FIG. 5 shows a synthesis example according to the invention; and

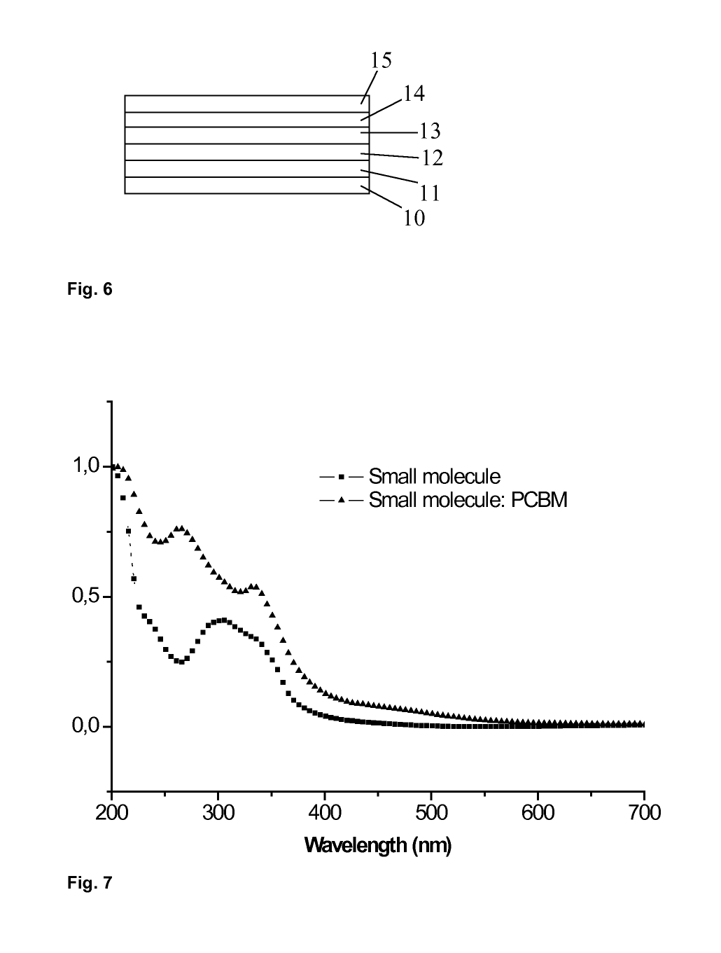

FIG. 6 shows an embodiment of a solar cell according to the invention.

FIG. 7 shows the UV-Vis spectrum of the small molecule compound of Example 2 and in combination with PCBM.

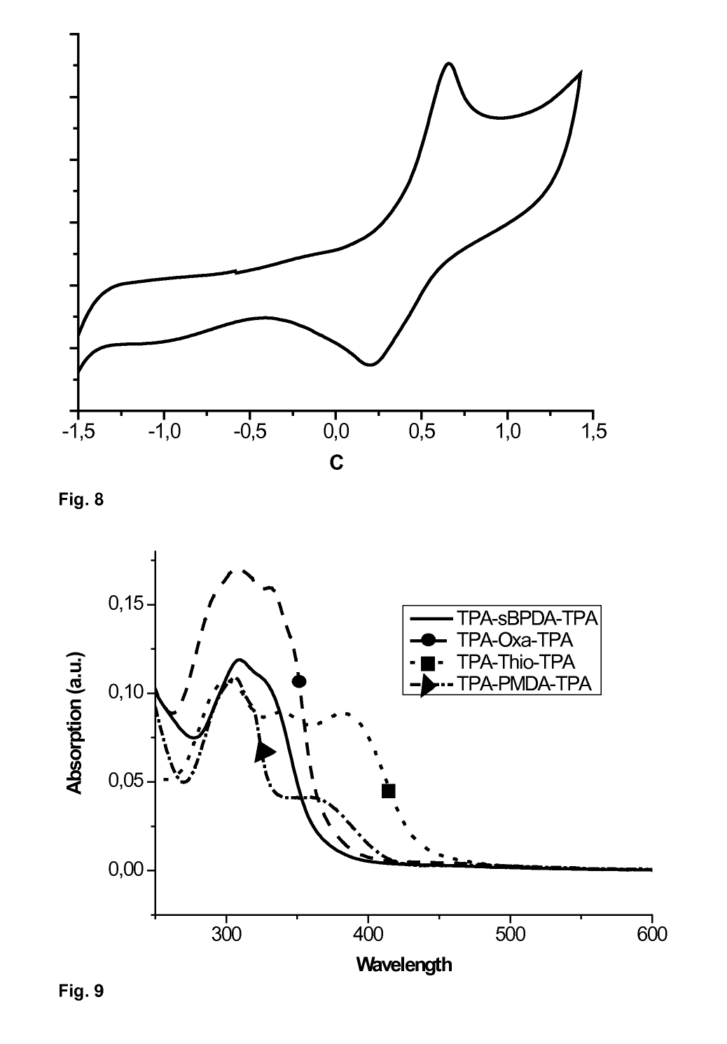

FIG. 8 shows the results of cyclic voltammetry of the small molecule compound of Example 2.

FIG. 9 shows the absorption spectra for several diimide compounds.

FIG. 1 shows an imide moiety, wherein an R group representing groups R2, R3, R4 is attached to the N atom of the imide.

In FIG. 2 a generic route is illustrated for a condensation reaction starting from an aromatic monoamine and an aromatic anhydride, the latter comprising a 5 membered hetero ring. In particular, 1,3-dihydro-2-benzofuran-1,3-dione is allowed to react with aniline thereby producing the aromatic imide product 2-phenyl-2,3-dihydro-1H-isoindole-1,3-dione.

FIG. 3 shows a generic route for preparing a photoactive material used in a solar cell according to the invention starting from a diamine and a dianhydride. In particular, an aromatic (representing group Ar) dianhydride comprising a conjugated L moiety is allowed to react with an aromatic diamine, forming a (poly)amic acid intermediate product, which is directly converted by thermal or chemical imidization into the polyimide backbone structure.

FIG. 4 shows 2 examples of imide backbones of small molecules and polymeric imides respectively.

FIG. 5 shows a specific example, wherein 1,3-dixo-1,3-dihydro-2-benzofuran-5-carboxylic acid is reacted with ethylene diamine in the presence of sulphuric acid (66% SO3) yielding a dianhydride, which is allowed to react with aniline-diphenylamine in glacial acetic acid using reflux, thereby obtaining 5,5′-(1,3,4-oxadiazole-2,5-diyl)bis(2-(4-(diphenylamino)phenyl)isoindoline-1,3-dione).

FIG. 6 illustrates a bulk heterojunction organic solar cell, wherein a substrate e.g. a transparent one from glass or plastic, or an (electrically isolated) thin metal foil, made e.g. from steel or aluminium, is indicated by reference numeral 10 and bears an electrode layer 11. On top of this electrode layer a charge transport layer 12 is arranged. An active layer 13 comprises a photoactive material according to the invention e.g. a donor and its counterpart (an acceptor like fullerene and its derivatives) in a blend. On top thereof a further charge transport layer 14 is positioned, as well as a transparent electrode layer 15.

Example 2 illustrates a preparation process of a compound used in the invention.

### Example 1

### Synthesis of 5,5′-(1,3,4-oxadiazole-2,5-diyl)bis(isobenzofuran-1,3-dione)

A 1 L threeneck flask equipped with stirring bar, condenser and N₂ inlet was charged with 77 g 1,3-dioxo-1,3-dihydroisobenzofuran-5-carboxylic acid (401 mmol) and 200 mL fuming sulfuric acid (65% free SO₃). The resulting suspension was heated to 75° C. and stirred until all 1,3-dioxo-1,3-dihydroisobenzofuran-5-carboxylic acid was dissolved. Hydrazine sulfate salt (23.7 g, 182 mmol) was added in portions and the reaction mixture was heated to 90° C. and stirred at this temperature for 4 hours.

The reaction mixture was poured onto crushed ice and the white precipitate was filtered off. The sticky white solids were washed by stirring in water until the pH was neutral. Residual water was removed by azeotropic distillation with 300 mL toluene and further drying overnight in a vacuum oven at 50° C. yielding the crude product as 61 g white solids.

30 g of the crude products were stirred in 200 mL acetic anhydride at 90° C. for 3 hours. The solids were filtered off and washed with hexane (3×100 mL) and dried overnight in a vacuum oven at 50° C. Yielding 21 g of the title compound as white solid (58 mmol, 29%).

### Example 2

### Synthesis of 5,5′-(1,3,4-oxadiazole-2,5-diyl)bis(2-(4-(diphenylamino)phenyl)isoindoline-1,3-dione)

A 250 mL threeneck flask equipped with stirring bar, condenser and N₂ inlet was charged with 10 g 5,5′-(1,3,4-oxadiazole-2,5-diyl)bis(isobenzofuran-1,3-dione) (27.6 mmol), 15.8 g of N1,N1-diphenylbenzene-1,4-diamine (2.2 eq.) and 100 mL glacial acetic acid. The resulting suspension was heated to reflux temperature and stirred at this temperature for 8 hours.

The reaction mixture was poured onto crushed ice and the orange precipitate was filtered off. The solids were washed with water (2×100 mL) and hexane (2×100 mL). The filtrate was dissolved in hot chloroform and filtered. The solution was allowed to cool down to room temperature and the precipitated orange solid was filtered off. The solids were dried overnight in a vacuum oven at 60° C. Yielding 20.8 g of the title compound as orange solid (24.6 mmol, 89%).

%). ¹H NMR (300 MHz, CDCl₃) δ ppm 8.90 (m, 2H), 8.83 (m, 2H), 8.35 (m, 2H), 7.48 (m, 12H), 7.36 (m, 12H), 7.27 (m, 4H); ¹³C NMR (100 MHz, CDCl₃) δ ppm 166.28, 166.18, 163.91, 147.93, 147.22, 134.28, 132.91, 132.84, 129.41, 128.90, 127.13, 125.01, 124.63, 124.52, 123.58, 122.77 and 121.98.

### Example 3

### Manufacturing Solar Cell

The small molecule of Example 2 and fullerene derivatives were dissolved in a 1:1 weight ratio in the respective solvents as indicated in the below Table 1 and the solution was stirred at 60° C. or 100° C. as indicated. The photoactive layers were spin-cast in air on clean glass substrates pre-patterned with indium tin oxide and a 60 nm thick film of poly(3,4-ethylenedioxythiophene)/poly(styrenesulfonic acid). The devices were finished by thermal evaporation of a LiF (1 nm)/Al (100 nm) cathode at 1×10⁻⁶ mbar. Electrical measurements were conducted in an N₂ controlled atmosphere in dark and under illumination of a Steuernagel SolarConstant 1200 metal halide lamp, which was set to 1 Sun intensity using a silicon reference cell and correcting for spectral mismatch.

TABLE 1

| solvent | T(° C.) | PCBM | J_{SC} | V_{OC} | FF | Eff |
|---|---|---|---|---|---|---|
| ODCB | 60 | [60] | 0.63 | 1.03 | 0.27 | 0.17 |
| ODCB | 60 | [70] | 0.64 | 0.67 | 0.26 | 0.11 |
| CB | 100 | [60] | 0.13 | 1.07 | 0.26 | 0.04 |
| CB | 100 | [70] | 0.59 | 0.57 | 0.26 | 0.09 |
| CHCl₃ | 60 | [60] | 0.10 | 1.05 | 0.25 | 0.03 |
| CHCl₃ | 60 | [70] | 0.30 | 0.89 | 0.25 | 0.07 |

FIG. 7 shows the UV-Vis spectrum of the title compound of Example 2 (lower line) and the title compound:PCBM in 1:1 ratio (upper line) both recorded in the film spincoated from CHCl₃.

FIG. 8 is a diagram showing the results of cyclic voltammetry performed with the title compound of Example 2. An oxidation potential of 0.44 V relative to Fc/Fc⁺ was found.

### Example 4

UV-Vis absorption of 5,5′-(1,3,4-oxadiazole-2,5-diyl)bis(2-(4-(diphenylamino)phenyl)isoindoline-1,3-dione). and 5,5′-(thiophene-2,5-diyl)bis(2-(4-(diphenylamino)phenyl)isoindoline-1,3-dione) was performed, thus the L moiety being either 1,3,4-oxadiazole or thiophene. For comparison TPA-PMDA-TPA, wherein TPA represents triphenylamine and PMDA stands for pyromellitic dianhydride, and TPA-sBPDA-TPA wherein SBPDA is biphenyl-tetracarboxylic acid dianhydride, were also examined. FIG. 9 shows the results at a concentration of 5 mg/L in CHCl3. An extension towards the visable spectrum wavelengths was observed going from TPA-PMDA-TPA via TPA-sBPA-TPA and TPA-Oxadiazole-TPA to TPA-Thiophene-TPA.

This Fig. shows the shift of light absorption towards the visible spectrum by varying the L moiety, TPA-Thiophene-TPA presenting the best results among these compounds examined.

### Example 5

Similar to Example 3 solar cells were made (spincoated from chloroform @ 60° C., 30 mg/mL total concentration, ratio small molecule photoactive material:[60]PCBM=1:3) from the photoactive materials of Ex. 4. Table 2 gives the results. * denotes devices that were annealed for 2 min at 120°, and the area of the solar cell is a=0.09 cm² or b=0.16 cm² respectively

TABLE 2

| L moiety | | J_{SC} | V_{OC} | FF | MPP |
|---|---|---|---|---|---|
| Thiophene | a | 0.121 | 0.58 | 0.29 | 0.0204 |
| | a* | 0.0748 | 0.48 | 0.23 | 0.00822 |
| | b | 0.177 | 0.59 | 0.29 | 0.0307 |
| Oxadiazole | a | 0.0862 | 0.48 | 0.3 | 0.0123 |
| | a* | 0.0506 | 0.39 | 0.24 | 0.00482 |
| | b | 0.087 | 0.39 | 0.3 | 0.0128 |
| PMDA | a | 0.0436 | 0.66 | 0.27 | 0.00769 |
| | a* | 0.0184 | 0.56 | 0.29 | 0.0019 |
| | b | 0.0413 | 0.67 | 0.27 | 0.00745 |
| sBPDA | a | 0.0715 | 0.68 | 0.26 | 0.0124 |
| | a* | 0.045 | 0.6 | 0.2 | 0.00536 |
| | b | 0.0673 | 0.69 | 0.25 | 0.0118 |

Similarly devices were spincoated from ODCB at 60° C., the area being 0.09 cm². The results are presented in Table 3 below.

TABLE 3

| Chromophore L | | J_{SC} | V_{OC} | FF | MPP |
|---|---|---|---|---|---|
| Thiophene | | 0.689 | 0.91 | 0.26 | 0.165 |
| | annealed | 0.873 | 0.75 | 0.34 | 0.22 |
| Oxadiazole | | 0.317 | 0.65 | 0.26 | 0.054 |
| | annealed | 0.508 | 0.69 | 0.29 | 0.101 |
| sBPDA | | 0.68 | 0.26 | 0.0715 | 0.0124 |
| | annealed | 0.6 | 0.2 | 0.045 | 0.00536 |

These results show that cells made from ODCB perform better than those from CHCl₃ and that annealing can be used to improve the performance. The best performance is 0.22% for thiophene as L moiety.

1. A solar cell, comprising at least a substrate, a cathode, a hole conductive layer, a bulk heterojunction photoactive layer of a blend of a donor material and an acceptor material, an electron conductive layer and an anode, wherein the blend comprises at least one photoactive material comprising a conjugated backbone system having:
i) the general formula R2-imide-Ar-L-Ar-imide-R3, wherein
Ar-L-Ar is a conjugated chromophore
imide is imide —OCNCO—
R2 and R3 are organic groups, bonded to the N atom of the respective imide and forming a conjugated bond with the respective imide; or.
ii) repeating units (R4-imide-Ar-L-Ar-imide)n, wherein
Ar-L-Ar is a conjugated chromophore, wherein L is a chromophore and Ar is a conjugated group,
imide is imide —OCNCO—
R4 is an organic group bonded to the N atom of the respective imide and forming a conjugated bond with the respective imide
and n is the number of repeating units.

2. The solar cell, according to claim 1, wherein R2, R3, R4 comprise a straight or branched alkyl solubilizing moiety.

3. The solar cell according to claim 1, wherein, R2, R3, R4 comprise an aromatic amino group.

4. The solar cell according to claim 1, wherein the imide is part of a 5 membered cyclic group having the structure I:

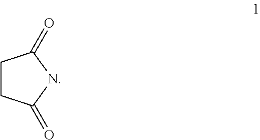

5. The solar cell according to claim 1, wherein the group L in the chromophore Ar-L-Ar comprises an organic group comprising at least one heteroatom selected from Si, S, N and O.

6. The solar cell according to claim 1, wherein the group L in the chromophore Ar-L-Ar comprises at least one 5 membered organic ring group comprising 1-3 heteroatoms selected from Si, S, N and O.

7. The solar cell according to claim 1, wherein the group L in the chromophore Ar-L-Ar is selected from the group comprising

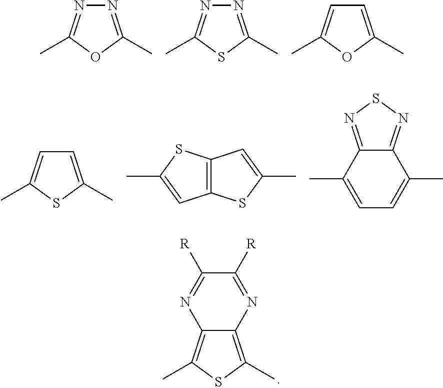

8. The solar cell according to claim 1, wherein Ar represents an aryl group.

9. The solar cell according to claim 1, wherein the imide—Ar comprises a phtalimide group.
